(19) United States
(12) Patent Application Publication
(10) Pub. No.: US 2026/0059748 A1
(43) Pub. Date: Feb. 26, 2026

(54) Technique for Multi-Site Cell Local Channel Separation

(71) Applicant: SK hynix Inc., Gyeonggi-do (KR)

(72) Inventor: Agus TJANDRA, San Jose, CA (US)

(21) Appl. No.: 18/813,013

(22) Filed: Aug. 23, 2024

(51) Int. Cl. H10B 43/27; G11C 16/04; H10B 43/10; H10B 43/35

(52) U.S. Cl. CPC H10B 43/27; G11C 16/0483; H10B 43/10; H10B 43/35

(57) ABSTRACT

A method for forming a split storage structure and an associated semiconductor memory device. The method forms oxide layers and nitride layers alternately stacked on a substrate, etches a hole through the oxide layers and the nitride layers, the hole having shorter axis sides and longer axis sides, etches the nitride layers to form recessed pockets between the oxide layers adjacent the longer axis sides, forms blocking layers and storage layers to fill the recessed pockets, forms a tunnel layer and a channel layer to cover walls of the storage layers inside the hole; provides an incomplete gap-filling layer in the hole, removes a part of the channel layer which is not covered by the gap-filling layer to form a split channel layer; completely removes the nitride layers to form recesses between the oxide layers; and forms conductive layers in the recesses where the nitride layers were completely removed.

### BACKGROUND

### 1. Field

The present invention relates to semiconductor memory devices and fabrication techniques thereof.

### 2. Description of the Related Art

A semiconductor memory device may include a plurality of memory cells capable of storing data. These memory cells may be coupled in series between select transistors to form a plurality of memory strings. Gates of the memory cells and the select transistors forming the memory strings may be stacked on each other for high integration density of the semiconductor device. A three-dimensional semiconductor device may be realized by using a gate stack structure including the gates stacked on each other. With regard to the realization of such a three-dimensional semiconductor device including the gate stack structure, various techniques for improving the operational reliability of the semiconductor device are being developed.

Semiconductor technology has advanced at a rapid pace and device dimensions have shrunk with advancing technology to provide faster processing and storage per unit space. In NAND devices, the string current needs to be high enough to obtain sufficient current to differentiate ON and OFF cells. The string current is dependent on the carrier mobility which is enhanced by enlarging the grain size of the silicon channel.

In a NAND flash, memory cells may be connected in series and an address line may be installed as a block unit. The NAND flash has advantages such as relatively low manufacturing cost, fast write speed, and suitable use for a large capacity. The vertical NAND flash memory typically stack memory cells vertically and use charge trapping structures.

Various insulators (dielectrics), semiconductors, and conductor materials are applied to process NAND devices. As an insulator material, a silicon oxide, a silicon nitride, a silicon oxynitride, a high dielectric (high-k) material, etc. may be used, and as a semiconductor material, a single crystal silicon, a polycrystalline silicon, an amorphous silicon, a germanium, a silicon-germanium, and various other compound semiconductors may be used.

As cell density increases, there is a need to process even smaller dimensional structures from the insulating and semiconductor materials being used to construct the semiconductor memory devices. In this context, embodiments of the present invention arise.

### SUMMARY

In accordance with one embodiment of the invention, there is provided a method for forming a split storage structure. The method forms oxide layers and nitride layers alternately stacked on a substrate, etches a hole through the oxide layers and the nitride layers, the hole having shorter axis sides and longer axis sides, etches the nitride layers to form recessed pockets between the oxide layers adjacent the longer axis sides, forms blocking layers and storage layers to fill the recessed pockets, forms a tunnel layer and a channel layer to cover walls of the storage layers inside the hole; provides an incomplete gap-filling layer in the hole, the incomplete gap filling layer being pinched along the shorter axis sides while leaving open areas along the longer axis sides, removes a part of the channel layer which is not covered by the incomplete gap-filling layer to form a split channel layer; completely removes the nitride layers to form recesses between the oxide layers; and forms conductive layers in the recesses where the nitride layers were completely removed.

In accordance with another embodiment of the invention, there is provided a semiconductor memory device comprising: a split channel layer adjacent an asymmetric hole in a stacked structure; a tunnel oxide in contact with the split channel layer; a charge trap disposed in a recess in the stacked structure and in contact with the tunnel oxide, a blocking oxide disposed in the recess in the stacked structure adjacent the asymmetric hole and in contact with the charge trap, wherein the split channel layer is divided from a silicon channel layer and dimensions of the charge trap and the blocking layer are not changed during division of the silicon channel layer.

### BRIEF DESCRIPTION OF THE DRAWINGS

FIGS. 1A-1D are diagrams depicting processing an elliptical cell memory structure in accordance with embodiments of the present invention.

FIGS. 2A-2B are diagrams depicting further processing of the elliptical cell memory structure in accordance with embodiments of the present invention.

FIGS. 3A-3C are diagrams depicting further processing of the elliptical cell memory structure in accordance with embodiments of the present invention.

FIGS. 4A-4E are diagrams depicting further processing of the elliptical cell memory structure in accordance with embodiments of the present invention.

FIGS. 5A and 5B are a composite flowchart illustrating one method for forming a memory storage structure in accordance with embodiments of the present invention.

FIG. 6 is a schematic illustrating a multi-dimensional memory device in accordance with embodiments of the present invention.

FIG. 7 is a schematic illustrating a stacked memory structure in accordance with embodiments of the present invention.

FIGS. 8A to 8C are schematic diagrams of multi-site cell structures of a semiconductor memory device in accordance with embodiments of the present disclosure.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will convey the scope of the present invention to those skilled in the art. Throughout the disclosure, like reference numerals refer to like parts throughout the various figures and embodiments of the present invention.

A detailed description of one or more embodiments of the invention is provided below along with accompanying figures that illustrate the principles of the invention. The invention is described in connection with such embodiments, but the invention is not limited to any embodiment. The scope of the invention encompasses numerous alternatives, modifications and equivalents. Numerous specific details are set forth in the following description in order to provide a thorough understanding of the invention. These details are provided for the purpose of example, and the invention may be practiced according to the claims without some or all of these specific details. For the purpose of clarity, technical material that is known in the technical fields related to the invention has not been described in detail so that the invention is not unnecessarily obscured.

To continue advanced NAND technology scaling, there is a need to have breakthrough in terms of cell scaling methodology as well as process innovation. In order to increase cell density, there are several different ways pursued in terms of vertical and lateral scaling. As the cell spacing becomes closer, process innovation is a driver for continuing to drive reliable cell performance, but the resultant higher cell density needs to be achieved at a reasonable cost of ownership.

In one embodiment of the present invention, overall cell reliability performances (e.g., like retention and charge trapping as well as other device metrics like program saturation) are met. In additional embodiment, the present invention provides configurations and methods for forming multi-site cells (MSC) for advanced NAND technology scaling to support future artificial intelligence (AI) and high-end data center market segments.

One embodiment of the present invention utilizes a local channel poly silicon (Si) separation step without the risk of causing cell stack dimensional changes during multi-site cell (MSC) process formation. In one embodiment, the present invention leverages the poor step coverage of gap-fill film such as tetraethyl orthosilicate (TEOS) to protect the cell area while leaving the sacrificial area open for a subsequent local channel separation process. While the present invention is not limited to any particular theory, since the TEOS gap-fill progresses has poor step coverage, the film deposition is pinched at a shorter axis direction for the elliptical (e.g., oval) cell shape in the MSC while leaving the longer axis direction area open. TEOS deposition can be made via processes such as described in U.S. Pat. No. 7,371,695 entitled “Use of TEOS oxides in integrated circuit fabrication processes” (the entire contents of which are incorporated herein by reference). TEOS deposition can be made via processes such as described in U.S. Pat. Appl. Publ. No. 2011/0250731 entitled “Preferential Dielectric Gapfill” (the entire contents of which are incorporated herein by reference).

In accordance with embodiments of the present invention, there is provided a method for dividing the channel layers without an oxidation cut process which may oxidize the charge trap nitride (CTN) during a channel poly-Si oxidation/cut process. Also, this method in one embodiment can secure sufficient storage nodes of sufficient area to store and retain charge in each split storage section. Typically, the charge storage area in in each split storage section would be at least 50% of the area in a conventional NAND cell, but the present invention is not limited to this value.

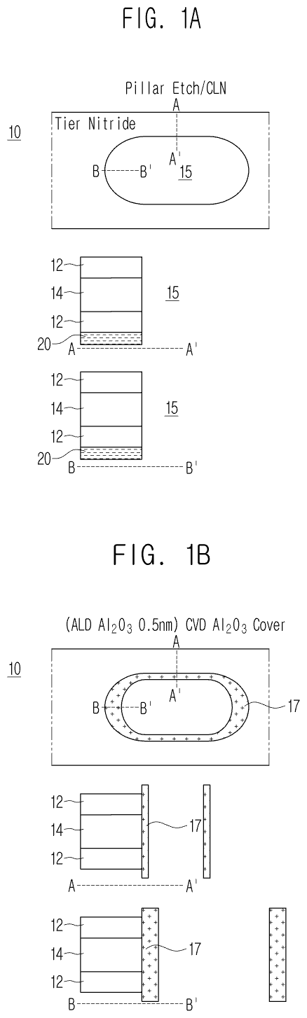

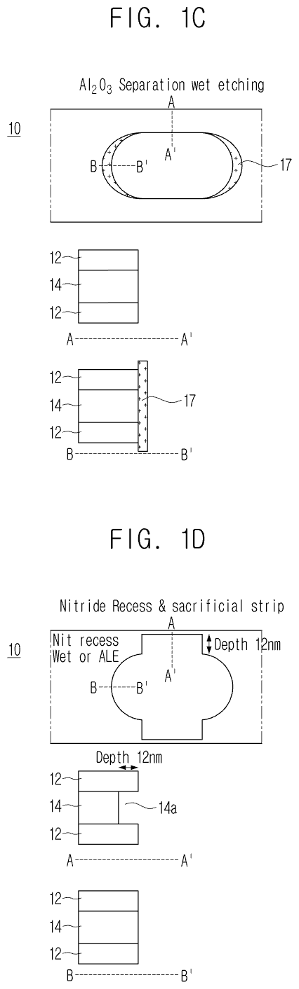

FIG. 1A is a diagram depicting processing an ellipse cell shape. While depicting an elliptical or oval cell shape, the present invention is not limited to these shape, but can be used with other asymmetric shaped holes such as for example triangular, quadruple, or star shaped holes.

As shown in FIG. 1A, a stacked alternating oxide/nitride (ON) structure 10 (having at least an oxide 12 and a nitride 14) is provided with an asymmetric opening 15 (in this example an oval) in the center. The asymmetric opening (or hole) formed in the stacked alternating oxide/nitride (ON) structure using masking, photolithography, and etching has shorter axis sides and longer axis sides. The asymmetry plays a role in assisting in the process of forming a split cell or a multi-split cell as the TEOS deposition noted above is deposited in recesses, and preferentially in spaces where the dimensions are shorter. The stacked alternating oxide/nitride (ON) structure 10 is formed on a substrate 20. For simplicity, substrate 20 is not shown in the other drawings. The stacked alternating oxide/nitride (ON) structure 10 can be formed with multiple oxide and nitride layers. The stacked alternating oxide/nitride (ON) structure 10 can be formed from a sequence of plasma assisted chemical vapor depositions where the plasma contains during one period of time oxygen and a silicon carrier such as silane and/or disilane, and thereafter contains during another period of time nitrogen and/or ammonia and a silicon carrier such as silane and/or disilane.

The thicknesses of the oxide layers and the nitride layer are shown in the cross section shown there on FIG. 1A, although the present invention is not limited to the dimensions shown. As shown in FIG. 1B, an Al₂O₃ layer 17 is deposited along the interior wall of the stacked alternating oxide/nitride (ON) structure 10 inside the opening 15, although the present invention is not limited to the dimension shown in FIG. 1B. For example, Al₂O₃ layer 17 of a thickness of 0.5 nm is deposited, but other thicknesses and alumina layers that are not perfectly stoichiometric can be used. In various embodiments, a non-conformal Al₂O₃ split condition where atomic layer deposition (ALD) or conventional Al₂O₃ CVD techniques would be used at deposition temperatures ranging from room temperature to ˜250° C. and optimizing the precursors such as Al(CH)₃ with H₂O or AlCl₃ with H₂O along with wafer to source gap height and pressure in the chamber to provide non-conformality. As shown in FIG. 1B, the thickness of the deposited Al₂O₃ layer 17 is thicker in the B-B′ direction. As shown in FIG. 1C, wet etching removes all of the Al₂O₃ layer 17 along the A-A′ direction and leaves some of the Al₂O₃ layer 17 along the B-B′ direction.

As shown in FIG. 1D, after a nitride etch and further after removal of the Al₂O₃ layer 17, nitride from the nitride layer 14 along the A-A′ direction was partially removed (as this section is not protected by any of the Al₂O₃ layer 17) to form a recess 14a (i.e., a recessed pocket). The nitride layer 14 along the B-B′ direction was not etched (as this section was protected by the Al₂O₃ layer 17).

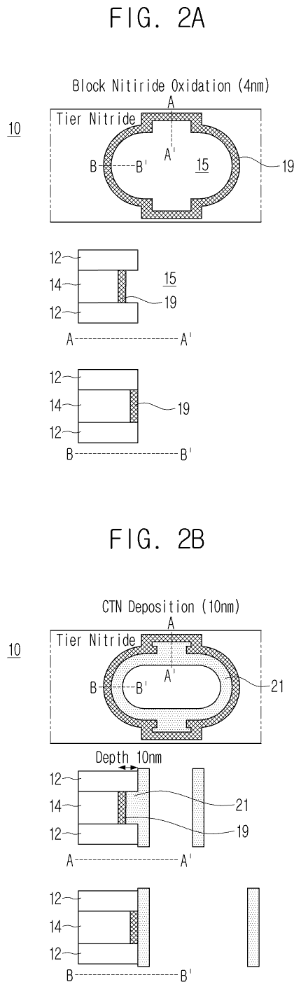

As shown in FIG. 2A, the nitride layer 14 is oxidized for example by exposure to oxygen species from an oxygen plasma, to create a relatively thin silicon oxide layer 19. As shown along the section in the A-A′ direction, silicon oxide layer 19 exists in a recess 14a between the oxide layers 12. As shown in FIG. 2B, a charge trap nitride (CTN} deposition is formed on the silicon oxide layer 19. For example, a silicon nitride 21 of 10 nm is deposited on the silicon oxide layer 19. The silicon nitride 21 exists in recess 14a between the oxide layers 12 and functions as a charge trap in the completed memory device.

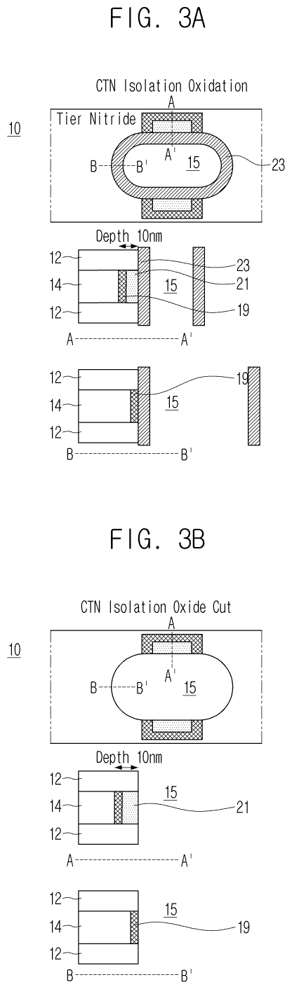

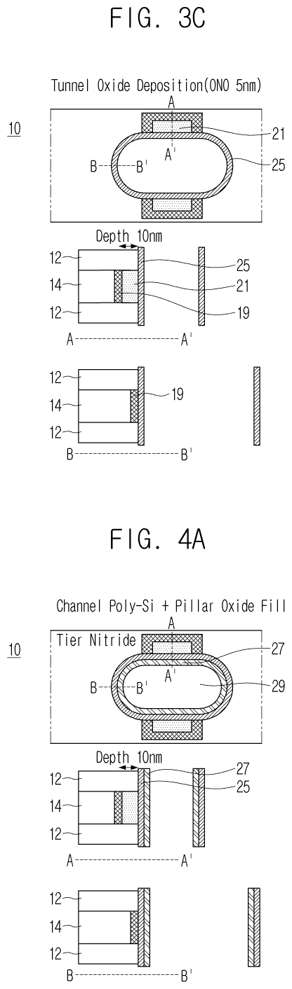

As shown in FIG. 3A, silicon nitride 21 is oxidized using for example exposure to oxygen species from an oxygen plasma to form oxide layer 23. As shown in FIG. 3A, the oxide layer 23 extends to oxide layer 12 and contacts silicon nitride 21 in between oxides 12 in the stacked structure 10, as seen in the A-A′ direction. As shown in FIG. 3B, the oxide layer 23 is removed for example by wet etching, leaving in the A-A′ direction silicon nitride 21 exposed to opening 15 and leaving in the B-B′ direction oxide layer 19 exposed to opening 15. As shown in FIG. 3C, an oxide 25 is formed on silicon nitride 21 to form an oxide layer 19/nitride 21/oxide 25 (a tunneling ONO layer). FIG. 3C shows a thickness 5 nm of the oxide 25, although the present invention is not limited to this thickness.

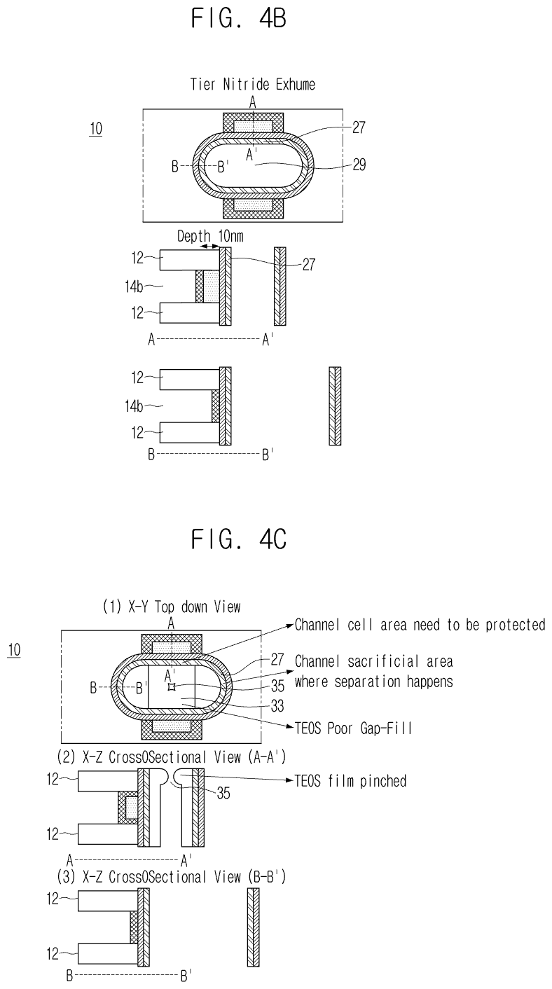

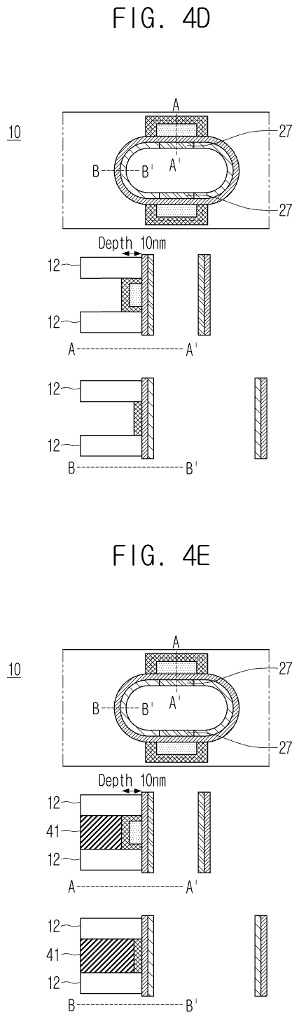

As shown in FIG. 4A, a poly-silicon layer 27 is formed on a wall of the oxide 25. Amorphous silicon can be deposited on the wall of the oxide 25, using for example a plasma chemical vapor deposition process with silane gas as the source of silicon. The amorphous silicon can be annealed to form poly-silicon layer 27. Alternatively, a poly-silicon layer 27 can be directly deposited using the plasma chemical vapor deposition process on the wall of the oxide 25. Subsequently, a pillar oxide 29 is formed to fill the opening 15. Pillar oxide 29 (although not shown in the cross sections shown in FIG. 4A) protects etching of oxide 25 during the next process. As shown in FIG. 4B, in the next process, nitride 14 is completely removed to form recess 14b where the nitride 14 (between oxides 12) had resided.

As shown in FIG. 4C, the opening 15 is opened by removal of the pillar oxide 29, and TEOS 33 is deposited therein. Due to the asymmetry, the TEOS 33 preferentially fills in the shorter A-A′ direction to form a central gap 35 formed toward the center of opening 15. In various embodiments, the following conditions can be used for non-conformal TEOS deposition where a low pressure chemical vapor deposition (LPCVD) deposition is used for TEOS deposition where TEOS precursors and O₃ along with NH₃ and a catalyst are supplied to a processing tool. The gas flow for each precursor and catalyst is typically optimized to achieve the non-conformality along with the deposition temperature and pressure. Normally, the deposition pressure is at 1 atm but can be reduced to ˜30 Torr, and the temperature of deposition ranges from 300-500° C. Furthermore, in other embodiments, different gap-filling materials besides TEOS can be used. These alternative gap-filling materials may include materials such as polysilazane PSZ (or other inorganic materials), flowable oxide fill materials like SiOC, carbon based film such as SiC or SiCN, amorphous carbon or other similar materials, where the step coverage or conformality (top to bottom sidewall coverage) can be tuned.

As shown in FIG. 4C, the poly-silicon layer 27 can be considered as a sacrificial poly-silicon layer and a channel cell poly-silicon layer. The top-down view shows where the channel cell area is to be protected and shows the channel sacrificial area where separation happens. As shown in FIG. 4D, the sacrificial poly-silicon layer is removed by etching around the TEOS 33 leaving the poly-silicon layer 27 in the channel cell, and then TEOS 33 is removed. Accordingly, in one embodiment of the present invention, the cell is split into two halves. Different cell structure geometries such as triangular, quadruple, and star-shaped structures, etc., with the narrow sections can be used to split the cell structure into multiple cells.

As shown in FIG. 4E, a metallic lead 41 can be formed in recesses 14b formed after complete removal of nitride 14 from between oxides 12.

### Split Cell Formation

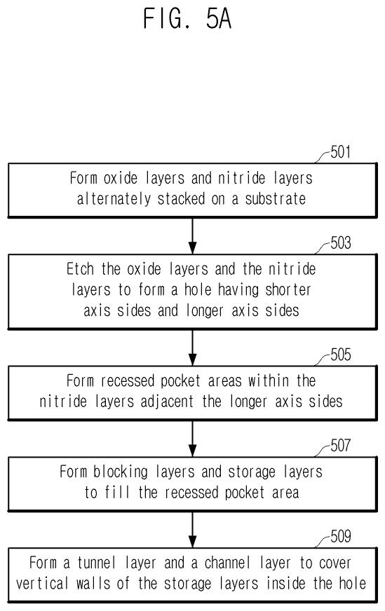

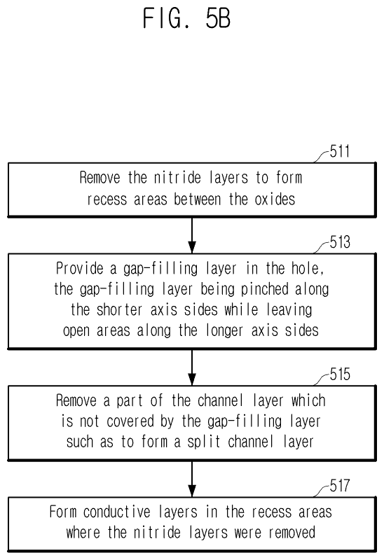

FIGS. 5A and 5B are composite flowcharts depicting a method for forming a split storage structure in accordance with one embodiment of the present invention.

Referring to FIG. 5A, at 501, the method forms oxide layers and nitride layers alternately stacked on a substrate. At 503, the method etches a hole through the oxide layers and the nitride layers, the hole having shorter axis sides and longer axis sides. At 505, the method etches the nitride layers to form recessed pockets between the oxide layers adjacent the longer axis sides. At 507, the method forms blocking layers and storage layers to fill the recessed pockets. At 509, the method forms a tunnel layer and a channel layer to cover walls of the storage layers inside the hole and provides a gap-filling layer in the hole. At 511, the method provides an incomplete gap-filling layer in the hole, the incomplete gap-filling layer being pinched along the shorter axis sides while leaving open areas along the longer axis sides. The incomplete gap-filling layer represents a non-optimized or poor step coverage gap-filling layer. At 513, the method removes a part of the channel layer which is not covered by the incomplete gap-filling layer to form a split channel layer. Referring to FIG. 5B, at 515, the method completely removes the nitride layers between the oxide layers to form recesses between the oxide layers. At 517, the method forms conductive layers in the recesses where the nitride layers are removed.

In one embodiment, providing the incomplete gap-filling layer comprises providing tetraethyl orthosilicate in the hole.

In another embodiment, forming a channel layer comprises forming silicon for the channel layer. In a further embodiment, this method removes a part of the channel layer by etching the silicon in that part of the channel layer. Etching the silicon uses a non-oxidation process to remove the silicon. The non-oxidation process avoids dimensional changes to the blocking layers and storage layers from additional oxidation

In another embodiment, the forming silicon comprises depositing amorphous silicon and thereafter annealing the amorphous silicon to form polycrystalline silicon. Alternatively, the forming silicon may deposit polycrystalline silicon.

In another embodiment, a first blocking layer of the blocking layers, a first storage layer of the storage layers, the tunnel layer, and a first half of the split channel layer can form a first storage structure. Furthermore, a second blocking layer of the blocking layers, a second storage layer of the storage layers, the tunnel layer, and a second half of the split channel layer can form a second storage structure.

In another embodiment, the first storage structure and the second storage structure form a multi-cell storage structure.

In another embodiment, the forming a tunnel layer comprises forming an oxide/nitride/oxide dielectric. In another embodiment, forming blocking layers comprises forming silicon oxides in between the oxide layers. In another embodiment, the forming storage layers comprises forming silicon nitride layers in between the oxide layers.

In another embodiment, prior to the forming the recessed pocket areas, an alumina film can be deposited on vertical walls of the hole along the shorter axis sides and along the longer axis sides, and a thickness of the alumina film along the shorter axis sides is thinner than the alumina film along the longer axis sides. Further, the forming the recessed pocket areas may comprise etching the alumina film from both the longer and shorter axis sides, and afterwards, etching a part of the nitride from the nitride layers between the oxide layers to form the recessed pocket areas.

### Memory System(s)

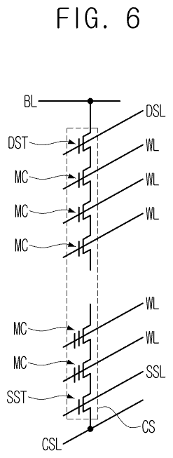

Referring to FIG. 6, the semiconductor memory device of the present invention may be a three-dimensional (3D) nonvolatile memory device or a two-dimensional (2D) nonvolatile memory device. According to one embodiment, the nonvolatile memory device may be a NAND flash memory device. The NAND flash memory device may include a memory cell string CS coupled to a bit line BL and a common source line CSL.

FIG. 6 illustrates a single memory cell string CS, but a plurality of memory cell strings may be coupled in parallel between the bit line BL and the common source line CSL. The memory cell string CS may include a source select transistor SST, a plurality of memory cells MC, and a drain select transistor DST disposed between the common source line CSL and the bit line BL. Each of the memory cells MC may comprise one of the memory structures described above with reference to FIGS. 1-5.

The source select transistor SST may control the electrical coupling between the plurality of memory cells MC and the common source line CSL. A single source select transistor SST may be disposed between the common source line CSL and the plurality of memory cells MC. Two or more source select transistors coupled in series to each other may be disposed between the common source line CSL and the plurality of memory cells MC. The source select transistor SST may be coupled to a source select line SSL. The operation of the source select transistor SST may be controlled by a source gate signal applied to the source select line SSL.

The plurality of memory cells MC may be disposed between the source select transistor SST and the drain select transistor DST. The memory cells MC between the source select transistor SST and the drain select transistor DST may be coupled in series to each other. The memory cells MC may be coupled to respective word lines WL. The operation of the memory cells MC may be controlled by cell gate signals applied to the word lines WL.

The drain select transistor DST may control the electrical coupling between the plurality of memory cells MC and the bit line BL. The drain select transistor DST may be coupled to a drain select line DSL. The operation of the drain select transistor DST may be controlled by a drain gate signal applied to the drain select line DSL. Each of the memory cells MC may store single-bit data or multi-bit data.

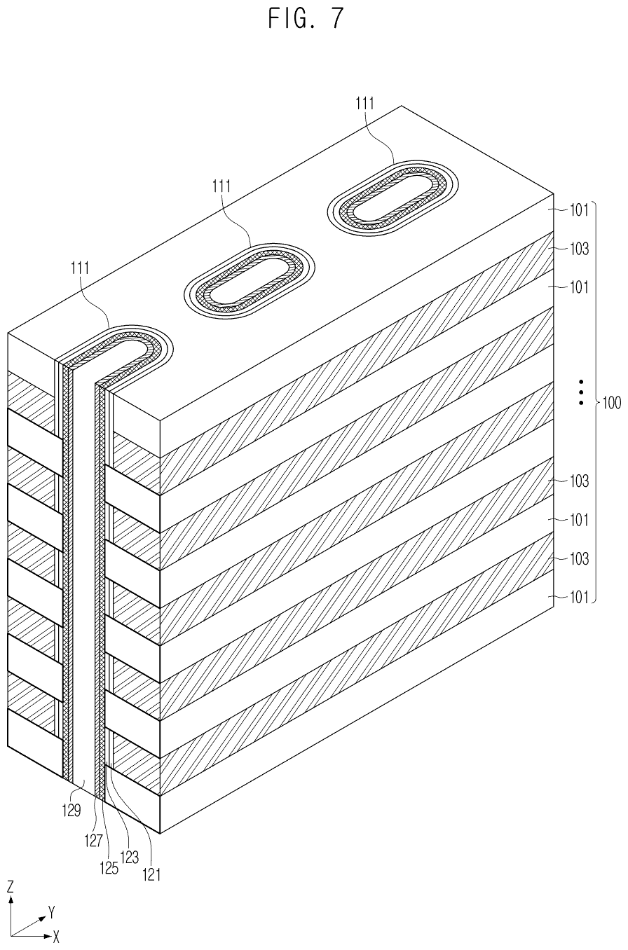

Referring to FIG. 7, the semiconductor memory device of the present invention may include a stacked body 100, a channel layer 127 (corresponding to split channel layer 27 in FIG. 4D), a tunnel insulating layer 125 (corresponding to tunnel oxide 25 in FIG. 3C), a data storage or charge trap layer 123 (corresponding to silicon nitride 21 in FIG. 3D), and a blocking insulating layer 121 (corresponding to oxide 19 in FIG. 3C).

The stacked body 100 may include interlayer insulating layers 101 and word lines 103 (corresponding to metallic line 41 in FIG. 4E) in contact with blocking insulator 121. Each of the interlayer insulating layers 101 and the word lines 103 may be parallel to an X-Y plane. The interlayer insulating layers 101 and the word lines 103 may be stacked in a Z-axis direction perpendicular to the X-Y plane. The interlayer insulating layers 101 may be disposed alternately with the word lines 103.

The word lines 103 may be insulated from each other by the interlayer insulating layers 101. The word lines 103 may be used as the gate electrodes of the memory cells MC described with reference to FIG. 1. The word lines 103 may include at least one of a doped semiconductor, metal, a metal nitride, and a metal silicide. The interlayer insulating layers 101 may include a silicon oxide layer.

The stacked body 100 may be penetrated by a hole 111 extending in the Z-axis direction. The sidewalls of the interlayer insulating layers 101 may be defined along the sidewall of the hole 111. Oxide 129 (such as oxide fill 29 in FIG. 4B) can fill the space in hole 111.

### Different Configurations

The present invention is not limited to the oval divided memory cell configuration(s) shown above. In one embodiment, the divided memory cell configuration (or multi-site cell structures) can have a triangular shape with charge traps (charge trap layer 123 or silicon nitride 21) disposed in recesses adjacent the triangular sides. In another embodiment, the divided memory cell configuration can have a quadruple shape with charge traps (charge trap layer 123 or silicon nitride 21) disposed in recesses adjacent the quadruple sides. In another embodiment, the divided memory cell configuration can have a pentagonal shape with charge traps (charge trap layer 123 or silicon nitride 21) disposed in recesses adjacent the quadruple sides. In another embodiment, the divided memory cell configuration can have a hexagonal shape with charge traps (charge trap layer 123 or silicon nitride 21) disposed in recesses adjacent the hexagonal sides.

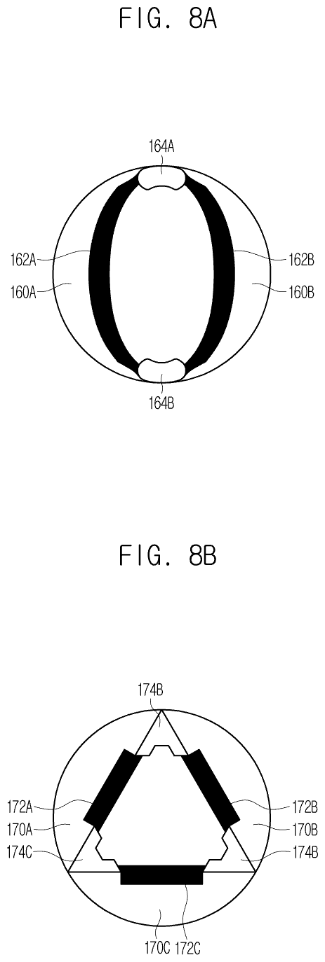

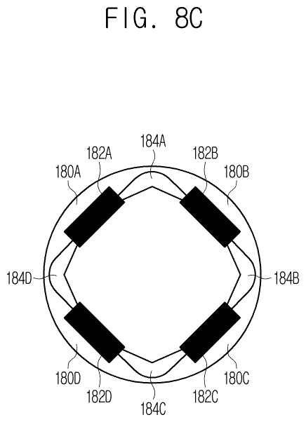

More specifically, FIGS. 8A to 8C are schematic diagrams of multi-site cell structures of a semiconductor memory device in accordance with different embodiments of the present disclosure.

As shown in FIG. 8A, the multi-site cell structure may include a dual site (or slit) cell. As shown in FIG. 8B, the multi-site cell structure may include a triple site cell. As shown in FIG. 8C, the multi-site cell structure may include a quadruple site cell. Alternatively, the multi-site cell structure may include a pentagon site cell or a hexagon site cell.

Referring to FIG. 8A, the dual site cell structure may include two cell patterns 160A, 160B. The cell patterns 160A, 160B may include two recessed storage patterns 162A, 162B, respectively. The recessed storage patterns 162A, 162B may have recessed pocket areas, which are separated by separation layers 164A, 164B. Each storage pattern can act as an independent cell. These elements and the process for forming the dual site cell structure have been described above with reference to FIGS. 1A to 4B.

Referring to FIG. 8B, the triple site cell structure may include two cell patterns 170A, 170B, 170C. The cell patterns 170A, 170B, 170C may include three recessed storage patterns 172A, 172B, 172C, respectively. The recessed storage patterns 172A, 172B, 172C may have recessed pocket areas, which are separated by separation layers 174A, 174B, 174C. Each storage pattern can act as an independent cell.

Referring to FIG. 8C, the quadruple site cell structure may include four cell patterns 180A, 180B, 180C, 180D. The cell patterns 180A, 180B, 180C, 180D may include four recessed storage patterns 182A, 182B, 182C, 182D, respectively. The recessed storage patterns 182A, 182B, 182C, 182D may have recessed pocket areas, which are separated by separation layers 184A, 184B, 184C, 184D. Each storage pattern can act as an independent cell.

### Semiconductor Memory Device(s)

Accordingly, in one embodiment of the present invention, there is provided a semiconductor memory device comprising: a split channel layer adjacent an asymmetric hole in a stacked structure; a tunnel oxide in contact with the split channel layer; a charge trap disposed in the stacked structure and in contact with the tunnel oxide, a blocking oxide disposed in a recess in the stacked structure adjacent the asymmetric hole and in contact with the charge trap, wherein the split channel layer is divided from a silicon channel layer, and dimensions of the charge trap and the blocking layer are not changed during division of the silicon channel layer.

In another embodiment, the split channel layer comprises a first channel layer disposed along a first longer axis side of the asymmetric recess and a second channel layer disposed along a second longer axis side of the asymmetric recess. Further, the blocking oxide, the charge trap, the tunnel oxide, the first channel layer, and the second channel layer comprise a multi-cell memory storage structure for the semiconductor memory device.

In another embodiment, the asymmetric recess has a longer axis side and a shorter axis side, wherein a ratio of the longer axis side to the shorter axis side ranges from 2 to 10.

Although the foregoing embodiments have been described in some detail for purposes of clarity of understanding, the invention is not limited to the details provided. There are many alternative ways of implementing the invention. The disclosed embodiments are illustrative and not restrictive. The present invention is intended to embrace all modifications and alternatives of the disclosed embodiment. Furthermore, the disclosed embodiments may be combined to form additional embodiments.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations, one or more features from a combination can in some cases be excised from the combination, and the combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A method for forming a split storage structure, comprising:
forming oxide layers and nitride layers alternately stacked on a substrate;
etching a hole through the oxide layers and the nitride layers, the hole having shorter axis sides and longer axis sides;
etching the nitride layers to form recessed pockets between the oxide layers adjacent the longer axis sides;
forming blocking layers and storage layers to fill the recessed pockets;
forming a tunnel layer and a channel layer to cover walls of the storage layers inside the hole;
providing an incomplete gap-filling layer in the hole, the incomplete gap-filling layer being pinched along the shorter axis sides while leaving open areas along the longer axis sides;
removing a part of the channel layer which is not covered by the incomplete gap-filling layer to form a split channel layer;
completely removing the nitride layers between the oxide layers to form recesses between the oxide layers; and
forming conductive layers in the recesses where the nitride layers were completely removed.

2. The method of claim 1, wherein the providing an incomplete gap-filling layer comprises providing tetraethyl orthosilicate in the hole.

3. The method of claim 1, wherein forming a channel layer comprises forming silicon for the channel layer.

4. The method of claim 3, wherein the removing a part of the channel layer comprises etching the silicon in that part of the channel layer.

5. The method of claim 4, wherein etching the silicon comprises using a non-oxidation process to remove the silicon.

6. The method of claim 5, wherein the non-oxidation process avoids dimensional changes to the blocking layers and storage layers from additional oxidation.

7. The method of claim 3, wherein the forming silicon comprises depositing amorphous silicon and thereafter annealing the amorphous silicon to form polycrystalline silicon.

8. The method of claim 3, wherein the forming silicon comprises depositing polycrystalline silicon.

9. The method of claim 1, wherein a first blocking layer of the blocking layers, a first storage layer of the storage layers, the tunnel layer, and a first half of the split channel layer form a first storage structure.

10. The method of claim 9, wherein a second blocking layer of the blocking layers, a second storage layer of the storage layers, the tunnel layer, and a second half of the split channel layer form a second storage structure.

11. The method of claim 10, wherein the first storage structure and the second storage structure form a multi-cell storage structure.

12. The method of claim 1, wherein forming a tunnel layer comprises forming an oxide/nitride/oxide dielectric.

13. The method of claim 1, wherein forming blocking layers comprises forming silicon oxides in between the oxide layers.

14. The method of claim 1, wherein forming storage layers comprises forming silicon nitride layers in between the oxide layers.

15. The method of claim 1, wherein
prior to the forming the recessed pockets, depositing an alumina film on walls of the hole along the shorter axis sides and along the longer axis sides, and
a thickness of the alumina film along the shorter axis sides is thinner than the alumina film along the longer axis sides.

16. The method of claim 15, wherein the forming the recessed pockets comprises:
etching the alumina film from both the longer and shorter axis sides; and
afterwards, etching a part of the nitride layers between the oxide layers to form the recessed pockets.

17. A semiconductor memory device comprising:
a split channel layer adjacent to an asymmetric hole in a stacked structure, the asymmetric hole having shorter axis sides and longer axis sides;
a tunnel oxide in contact with the split channel layer;
a charge trap disposed in a recess in the stacked structure and in contact with the tunnel oxide; and
a blocking oxide disposed in the recess in the stacked structure adjacent to the asymmetric hole and in contact with the charge trap,
wherein
the split channel layer is divided from a silicon channel layer, and
spatial dimensions of the charge trap and the blocking oxide are not changed during division of the silicon channel layer.

18. The device of claim 17, wherein the split channel layer comprises a first channel layer disposed along a first longer axis side of the asymmetric hole and a second channel layer disposed along a second longer axis side of the asymmetric hole.

19. The device of claim 18, wherein
the blocking oxide, the charge trap, the tunnel oxide, the first channel layer, and the second channel layer comprise a multi-cell memory storage structure for the semiconductor memory device.

20. The device of claim 17, wherein a ratio of the longer axis side to the shorter axis side ranges from 2 to 10.
